(19) United States
(12) Patent Application Publication
(10) Pub. No.: US 2013/0068516 A1
(43) Pub. Date: Mar. 21, 2013

(54) HIGH IO SUBSTRATES AND INTERPOSERS WITHOUT VIAS

(71) Applicant: Ilyas Mohammed, Santa Clara, CA (US)

(72) Inventor: Ilyas Mohammed, Santa Clara, CA (US)

(73) Assignee: TESSERA RESEARCH LLC, San Jose, CA (US)

(21) Appl. No.: 13/235,725

(22) Filed: Sep. 19, 2011

(51) Int. Cl. H05K 1/11; H05K 3/10

(52) U.S. Cl. 174/261; 29/846

(57) ABSTRACT

An interconnection component includes a substrate having first and second opposed major surfaces defining a thickness of less than 1000 microns and a first slot extending between the first and second surfaces, the first slot being enclosed by the substrate at the first and second surfaces. The first slot defines an edge surface between the first surface and the second surface. First conductive traces extend along the first surface and are electrically connected with first contact pads that overlie the first surface. Second conductive traces extend along the second surface and electrically connected with second contact pads that overlie the second surface. Interconnect traces extend along the edge surface of the first slot. Each interconnect trace directly connects at least one first trace with at least one second trace.

### BACKGROUND OF THE INVENTION

Interconnection components, such as interposers and substrates are used in electronic assemblies to facilitate connection between components with different connection configurations, to provide needed spacing between components in a microelectronic assembly, or to facilitate handling of components. Interposers can include a dielectric element in the form of a sheet or layer of dielectric material having numerous conductive traces extending on or within the sheet or layer. The traces can be provided in one level or in multiple levels throughout a single dielectric layer, separated by portions of dielectric material within the layer. The interposer can also include conductive elements such as conductive vias extending through the layer of dielectric material to interconnect traces in different levels. Some interposers are used as components of microelectronic assemblies. Microelectronic assemblies generally include one or more packaged microelectronic elements such as one or more semiconductor chips mounted on a substrate. The conductive elements of the interposer can include the conductive traces and terminals that can be used for making electrical connection with a larger substrate or circuit panel in the form of a printed circuit board (“PCB”) or the like. This arrangement facilitates electrical connections needed to achieve desired functionality of the devices. The chip can be electrically connected to the traces and hence to the terminals, so that the package can be mounted to a larger circuit panel by bonding the terminals of the circuit panel to contact pads on the interposer. For example, some interposers used in microelectronic packaging have terminals in the form of exposed ends of pins or posts extending through the dielectric layer. In other applications, the terminals of an interposer can be exposed pads or portions of traces formed on a redistribution layer.

Semiconductor chips and other microelectronic elements are commonly provided in packages that facilitate handling of the chip during manufacture and during mounting of the chip on an external substrate such as a circuit board or other circuit panel. For example, many semiconductor chips are provided in packages suitable for surface mounting. Numerous packages of this general type have been proposed for various applications. Most commonly, such packages include a dielectric element, commonly referred to as a “chip carrier” with terminals formed as plated or etched metallic structures on the dielectric. These terminals typically are connected to the contacts of the chip itself by features such as thin traces extending along the chip carrier itself and by fine leads or wires extending between the contacts of the chip and the terminals or traces. In a surface mounting operation, the package is placed onto a circuit board so that each terminal on the package is aligned with a corresponding contact pad on the circuit board. Solder or other bonding material is provided between the terminals and the contact pads. The package can be permanently bonded in place by heating the assembly so as to melt or “reflow” the solder or otherwise activate the bonding material.

Many packages include solder masses in the form of solder balls, typically about 0.1 mm and about 0.8 mm (5 and 30 mils) in diameter, attached to the terminals of the package. A package having an array of solder balls projecting from its bottom surface is commonly referred to as a ball grid array or “BGA” package. Other packages, referred to as land grid array or “LGA” packages are secured to the substrate by thin layers or lands formed from solder. Packages of this type can be quite compact. Certain packages, commonly referred to as “chip scale packages,” occupy an area of the circuit board equal to, or only slightly larger than, the area of the device incorporated in the package. This is advantageous in that it reduces the overall size of the assembly and permits the use of short interconnections between various devices on the substrate, which in turn limits signal propagation time between devices and thus facilitates operation of the assembly at high speeds.

Packaged semiconductor chips are often provided in “stacked” arrangements, wherein one package is provided, for example, on a circuit board, and another package is mounted on top of the first package. These arrangements can allow a number of different chips to be mounted within a single footprint on a circuit board and can further facilitate high-speed operation by providing a short interconnection between packages. Often, this interconnect distance is only slightly larger than the thickness of the chip itself. For interconnection to be achieved within a stack of chip packages, it is necessary to provide structures for mechanical and electrical connection on both sides of each package (except for the topmost package). This has been done, for example, by providing contact pads or lands on both sides of the substrate to which the chip is mounted, the pads being connected through the substrate by conductive vias or the like. Solder balls or the like have been used to bridge the gap between the contacts on the top of a lower substrate to the contacts on the bottom of the next higher substrate. The solder balls must be higher than the height of the chip in order to connect the contacts. Examples of stacked chip arrangements and interconnect structures are provided in U.S. Patent App. Pub. No. 2010/0232129 (“the '129 Publication”), the disclosure of which is incorporated by reference herein in its entirety.

Despite all of the above-described advances in the art, still further improvements in making and testing microelectronic packages would be desirable.

### SUMMARY OF THE INVENTION

An aspect of the present disclosure relates to an interconnection component. The interconnection component includes a substrate having first and second opposed major surfaces defining a thickness of less than 1000 microns and a first slot formed extending between the first and second surfaces, the first slot being enclosed by the substrate at the first and second surfaces. The first slot defines an edge surface between the first surface and the second surface. First conductive traces extend along the first surface and are electrically connected with first contact pads that overlie the first surface. Second conductive traces extend along the second surface and electrically connected with second contact pads that overlie the second surface. Interconnect traces extend along the edge surface of the first slot. Each interconnect trace directly connects at least one first trace with at least one second trace.

The first slot can have a length in the first lateral direction and a width in a second lateral direction perpendicular to the first lateral direction. The length and width can define a ratio of at least 10 to 1. In an embodiment, at least ten interconnect traces along edge the surface of the first slot.

In an embodiment, the first and second contact pads can be usable to bond the interconnection component to at least one of a microelectronic element or a circuit panel. At least one of the first contact pads or the second contact pads can be configured for bonding to element contacts on a face of a microelectronic element and at least one of the first contact pads or the second contact pads configured for bonding to circuit contacts on a face of a circuit panel.

The first traces can be included in a first redistribution layer that overlies the first surface of the substrate. A second redistribution layer can be included that overlies the first redistribution layer. In such an embodiment, the first contact pads are in the second redistribution layer. The second redistribution layer can have third traces formed therein that are electrically connected to the first traces, and the first contact pads can be joined to the third traces. At least one of the third traces overlies the first slot. A first dielectric layer can overlie at least portions the first surface of the substrate and can fill spaces between the first and third traces. The first dielectric layer can further fill at least some of the first slot. The second traces can be included in a third redistribution layer that overlies the second surface of the substrate. A fourth redistribution layer can be included that overlies the third redistribution layer, and the second contact pads can be in the fourth redistribution layer. The fourth redistribution layer can have fourth traces formed therein that are electrically connected to the second traces, and the second contact pads can be joined to the fourth traces. In an embodiment, the first traces are in a first redistribution layer, and the interconnection component further includes a plurality of additional redistribution layers overlying the first redistribution layer. One of such additional redistribution layers can be an outermost redistribution layer, and the first contact pads can be in the outermost redistribution layer.

At least one of the first or second contact pads can be displaced in one or more lateral directions from a boundary of the first slot. Additionally or alternatively, at least one of the first or second contact pads can overlie at least a portion of the first slot.

In an embodiment, the substrate can further include a second slot formed therethrough that is open to the first surface and the second surface. The interconnection component in such an embodiment can further include interconnect traces extending along the edge surface of the second slot, each interconnect trace directly connecting at least one first trace with at least one second trace. The first slot can further be one of a plurality of slots included in the substrate, each slot being open to the first surface and the second surface. The interconnection component can, thus, include interconnect traces extending along the edge surface of each of the plurality of slots, each interconnect trace directly connecting at least one first trace with at least one second trace. In an embodiment, the first slot can also extend in a second lateral direction between the first end and the second end such that the slot is non-linear. The first slot can be filled with a dielectric material that extends along portions of the edge surface uncovered by the interconnect traces and fills spaces between the interconnect traces.

The substrate can be of a material having a coefficient of thermal expansion (“CTE”) of less than about 10 parts per million per degree, Celsius (PPM/° C.). Such a material can be selected from the group consisting of: silicon, glass, ceramic, liquid crystal polymer, or combinations thereof. In an embodiment, the substrate can include an inner layer of a semiconductor material and an outer layer of a dielectric material overlying the inner layer. The outer layer can define the first surface, the second surface and the edge surface of the first slot. The outer layer can further define a peripheral edge.

The substrate can define a peripheral edge extending between the first and second surfaces, and at least some interconnect traces can also extend along the peripheral edge and directly connect at least one first trace with at least one second trace.

The first slot can have a first width adjacent the first surface and a second width adjacent the second surface. The first width can be between about 50 and 250 microns and the second width can be between about 10 and 100 microns. In a similar embodiment, the edge surface of the first slot can form a first angle with the second surface of between about 30 degrees and 150 degrees. The angle with the second surface can further be between about 50 degrees and 130 degrees or about 54 degrees.

A microelectronic assembly can include a microelectronic element having a first surface, a second surface spaced apart from the first surface, and conductive contacts exposed at the first surface. The assembly can also include an interconnection component according to one or more of the embodiments discussed above. The microelectronic element can be mounted on the interconnection component over the first side of the substrate, and the conductive contacts can be electrically connected to at least some of the first contact pads. The microelectronic element can be a first microelectronic element, and the assembly can further include a second microelectronic element having a first surface, a second surface spaced apart from the first surface, and conductive contacts exposed at the first surface. The second microelectronic element can be mounted on the interconnection component such that at least some of the contacts thereof are electrically interconnected to at least some of the first contact pads. In an embodiment the first and second microelectronic elements can be electrically interconnected with one another through the interconnection component. The contacts can face the first contact pads and can be joined thereto. Such an assembly can further include solder balls joined to at least some of the second contact pads. A microelectronic system, can include such a microelectronic assembly and one or more other electronic components electrically connected to the microelectronic assembly. At least one of the other electronic components can be one of an active or passive device.

Another aspect of the present disclosure relates to an interconnection component. The interconnection component includes a substrate having first and second opposed major surfaces defining a thickness of less than 1000 microns, a first slot formed therethrough that extends in a first lateral direction between a first end and a second end and is open to the first surface and the second surface. The first slot defines a first edge surface between the first surface and the second surface. A second edge surface extends between outer peripheries of the first surface and the second surface. First conductive traces extend along the first surface and electrically connect with first contact pads that overlie the first surface. Second conductive traces extending along the second surface and electrically connect with second contact pads that overlie the second surface. First interconnect traces extend along the edge surface of the first slot. Second interconnect traces extend along the edge surface of substrate. Each of the first and second interconnect traces directly connecting at least one first trace with at least one second trace.

Another aspect of the present disclosure relates to a method for making an interconnection component. The method includes forming a first slot in a substrate having first and second opposed major surfaces defining a thickness of less than 1000 microns. The first slot is formed through the substrate such that it is open to the first surface and the second surface. The first slot defines an edge surface extending between the first surface and the second surface. The method further includes forming first conductive traces extending along the first surface, second conductive traces extending along the second surface, and interconnect traces extending along portions of the edge surface of the first slot. Each interconnect trace directly connects at least one first trace with at least one second trace. The method further includes forming first contact pads overlying portions of the first surface and electrically connected with at least some of the first traces and second contact pads overlying portions of the second surface and electrically connected with at least some of the second traces.

The interconnect traces can be formed simultaneously with and by the same process as one of the first traces and the second traces. At least one of the first or second traces can be formed from a single metal layer from which the first or second contact pads are respectively formed. In an embodiment, a first metal layer can be used to form the first traces, and a second metal layer overlying the first traces can be used to form the first contact pads.

The substrate can be of a semiconductor material, and the method can further include the step of forming a dielectric coating over the substrate prior to the steps of forming traces and forming contact pads. In an embodiment, the dielectric coating can substantially cover the first and second opposed surfaces and the edge surface of the slot.

The first slot can be formed such that the edge surface forms an angle with the second surface that is between about 30 degrees and 150 degrees. The first slot can be formed by a first step including removing material from the substrate to give the first slot a desired length and width and a second step including forming the angle of the edge surface. The first slot can be one of a plurality of slots, each slot having some of the interconnect traces formed along respective edge surfaces thereof. Some of the interconnect traces can further be formed extending along portions of the peripheral edge of the substrate. Corresponding pairs of at least some of the first and second traces can extend to a boundary of the peripheral edge, and corresponding interconnect traces can be bonded between and can connect the corresponding pair of a first trace and a second trace.

In an embodiment the first traces can be formed in a first redistribution layer. In such an embodiment, the method can further include forming at least one additional redistribution layer overlying the first redistribution layer. One of the additional redistribution layers can be an outer redistribution layer, and the first contact pads can be formed in the outermost redistribution layer. A first dielectric layer can overlie at least portions the first surface of the substrate and can fill spaces between the traces. The first contact pads can be exposed at a surface of the first dielectric layer.

At least one of the first or second contact pads can be formed in a location such that it is displaced in one or more lateral directions from a boundary of the first slot. Further, at least one of the first or second contact pads can be formed overlying at least a portion of the first slot.

An embodiment of the method can further include the step of filling the first slot with a dielectric material that extends along portions of the edge surface uncovered by the interconnect traces and fills spaces between the interconnect traces.

The first traces and the interconnect traces can be formed by plating a first conductive layer over the first surface of the substrate and the edge surface of the first slot and removing portions of the first conductive layer. The second traces can then be formed by plating a second conductive layer on the second surface of the substrate and removing portions of the second conductive layer. The first and second traces and the interconnect traces can alternatively be formed by depositing conductive metal using one of laser writing or printing.

Another aspect of the present disclosure relates to a method for making a microelectronic package. The method includes assembling a microelectronic element having a front face, a back face remote from the front face, and contacts exposed at the front face with a substrate. The substrate has first and second opposed major surfaces defining a thickness of less than 1000 microns and a first slot formed therethrough that is open to the first surface and the second surface. The first slot definEs an edge surface between the first surface and the second surface. First conductive traces extend along the first surface and electrically connect with first contact pads that overlie the first surface. Second conductive traces extend along the second surface and electrically connect with second contact pads that overlie the second surface. Interconnect traces extend along the edge surface of the first slot. Each interconnect trace directly connects at least one first trace with at least one second trace. Corresponding pairs of at least some of the first and second traces extend to directly contact respective ones of the interconnect traces, and the respective interconnect traces are bonded between and connect the corresponding pair of a first trace and a second trace. The microelectronic element is assembled with the substrate such that the microelectronic element is bonded to the interconnection component over the first surface of the substrate and the contacts are electrically connected to at least some of the first contact pads.

In an embodiment the contacts can face the first contact pads and can be joined thereto. Such an embodiment can further include forming solder balls on at least some of the second contact pads. Alternatively, the contacts can face away from the first contacts pads and can be electrically connected therewith using wire bonds.

### BRIEF DESCRIPTION OF THE DRAWINGS

Various embodiments of the present invention will be now described with reference to the appended drawings. It is appreciated that these drawings depict only some embodiments of the invention and are therefore not to be considered limiting of its scope.

FIG. 1 is a microelectronic assembly including an interconnection component according to an embodiment of the present disclosure;

FIG. 2 is a microelectronic assembly including an interconnection component according to another embodiment of the present disclosure;

FIG. 3 is a microelectronic assembly including an interconnection component according to another embodiment of the present disclosure;

FIG. 4 is a microelectronic assembly including an interconnection component according to another embodiment of the present disclosure;

FIG. 5 is a variation of a microelectronic assembly including a variation of the interconnection component of FIG. 2;

FIG. 6 is a variation of the microelectronic assembly of claim 1 including multiple interconnection components;

FIGS. 7A and 7B are examples of connections between conductive elements in an interconnection component according to various embodiments of the present disclosure;

FIG. 8 is a portion of an interconnection component according to an embodiment of the present disclosure during a step in a method for fabrication thereof;

FIGS. 9A-9D show schematic views of a portion of an interconnection component according to various embodiments of the present disclosure;

FIGS. 10-13 show a portions of an interconnection component according to an embodiment of the present disclosure during further steps in a method for fabrication thereof; and

FIG. 14 is a system including the microelectronic assembly of FIG. 1.

### DETAILED DESCRIPTION

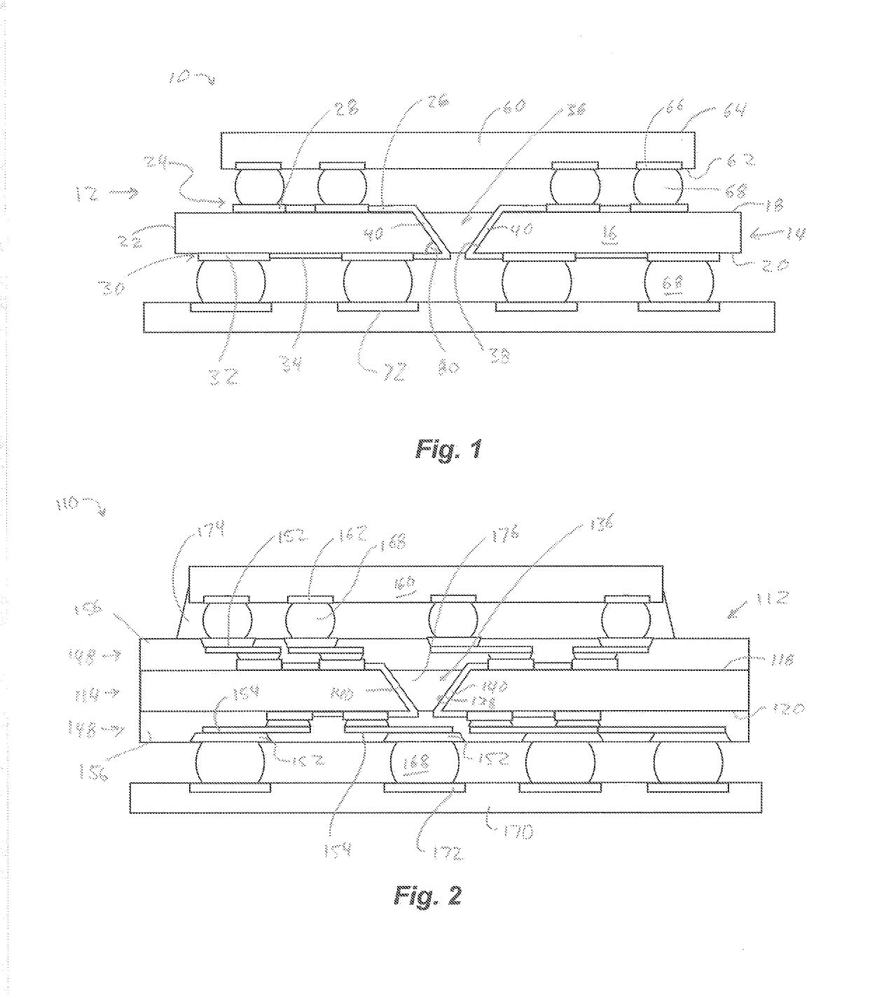

Turning now to the figures, where similar numeric references are used to refer to similar features, FIG. 1 shows a microelectronic assembly 10 that includes a microelectronic package 12 on a circuit panel 70. Package includes a microelectronic unit 60 on an interconnection component 14 according to an embodiment of the present disclosure. In the embodiment shown interconnection component 14 is in the form of a substrate 16 having a first wiring layer 24 and a second wiring layer 30 exposed on opposing sides thereof and configured for connection to various external devices and structures that can include, for example, the circuit panel 70 and microelectronic element 60 shown in FIG. 1.

Substrate 16 can include a first surface 18 and a second surface 20 that extend in generally lateral directions and are substantially parallel to each other defining a thickness of substrate 16 therebetween. In an embodiment, substrate 16 can have a thickness of at least 10 microns and up to about 500 microns. Such thicknesses can be used when substrate 16 is used in an interconnection component 14 in the form of a package substrate. In other embodiments substrate 16 can have a thickness of at least 500 microns and can be used in an interconnection component 12 structured according to the embodiment of FIG. 1 or described elsewhere herein that is in the form of an interposer. Substrate can be formed from a dielectric material such as a polymeric resin material such as polyimide, BT-Resin or fiber-reinforced epoxy. Substrate 16 can also be of a material having a low coefficient of thermal expansion (“CTE”), such as 12 parts per million per degree Celsius (“ppm/° C.”) or below. A liquid crystal polymer (“LCP”) material or other materials of the types listed herein can have such a CTE or can be made in certain variations or mixtures including one or more of the above materials, in addition to others, to achieve a desired CTE. Peripheral edge surface 22 extends between the first and second surfaces 18,20 in the direction of the thickness and defines an outer periphery of substrate 16.

First wiring layer 24 is exposed on first surface 18 of substrate 16 and can include a plurality of first contact pads 28 connected with a plurality of first traces 26. The traces and contact pads can be made from a conductive metal such as copper, gold, aluminum, nickel, or combinations thereof. In the embodiment shown first contact pads 26 are arranged in an array that substantially matches an array in which contacts 66 of microelectronic element 60 are arranged. Such a configuration can be used to connect microelectronic element 60 in the flip-chip configuration shown in FIG. 1, wherein front surface 62 of microelectronic element 60 faces first surface 18 of interconnection component 14 and microelectronic contacts 66, which are formed on front surface 62, are bonded to first contact pads 28 using solder balls 68. Other arrangements for first contact pads 28 are possible and can be configured to connect to various components using various techniques. In an embodiment, the array of first contact pads 28 can be in the form of a grid having a plurality of spaced-apart rows and columns of first contact pads 28. The distance between contact pads in such an array can be referred to as a pitch of the array and can be uniform and equal in both the row and column directions or can vary between directions. The pitch can also be an average pitch or a minimum or maximum pitch in a non-uniform array.

Second wiring layer 30 is exposed on second surface 20 of substrate 16 and can include a plurality of second contact pads 34 connected with a plurality of second traces 32. In the embodiment shown second contact pads 34 are arranged in an array that substantially matches an array in which contacts 72 are arranged on circuit panel 70. Such a configuration can be used to connect package 12, including interconnection component 14 and microelectronic element 60 to circuit panel using solder balls 68 bonded between second contact pads 34 and circuit contacts 72. Other arrangements for second contact pads 34 are possible and can be configured to connect to various components using various techniques. An arrangement of second contact pads 34 in an array can vary according to the variations discussed above with respect to an array of first contact pads 28.

Substrate 16 includes at least one slot 36 formed therein that forms an opening through the thickness of substrate 16 between first surface 18 and second surface 20. Slot 36 can extend in at least one lateral direction (for example, in and out of the page as shown in FIG. 1) defining a length thereof between two closed ends that are spaced apart from the outer periphery of substrate 16. Slot 36 further has a width in a direction perpendicular to the length thereof. This width can be measured at a location near first surface 18, second surface 20 or at a location therebetween. In an embodiment, the length can be greater than the width by a ratio of at least 10 to 1. Slot 36 defines an edge surface 38 extending at least partially in the direction of the thickness of substrate 16 between and intersecting first surface 18 and second surface 20. As shown in FIG. 1 at least some of first traces 26 extend surface 18 to the intersection between first surface 18 and edge surface 38. Similarly at least some of second traces 32 extend along second surface 20 to the intersection between second surface 20 and edge surface 38.

Interconnection traces 40 extend along edge surface 38 and can be configured to electrically connect one first trace with a corresponding second trace 32. To achieve such a connection using an interconnection trace 40, a first trace 26 and a corresponding second trace can be substantially aligned in a vertical plane, at least at locations where they, respectively reach the intersection of first surface 18 or second surface 20 with edge surface 38. In such an arrangement, an interconnection trace 40 that extends along edge surface 38 and such a theoretical vertical plane can connect with the first trace 26 and the second trace 32. Alternatively, the first trace 26 and the second trace 32 can be in a non-aligned relationship and interconnection trace 40 can be configured to extend in multiple lateral directions along edge surface 38 between first trace 26 and second trace 32. Multiple interconnection traces can extend through a single slot 36 along edge surface 38 thereof connecting multiple pairs of corresponding first traces 26 and second traces 32. In an example, at least 10 of such interconnection traces 40 can extend through a single slot 36. For example at least five interconnection traces 40 can extend along opposing sides of slot 36. Additionally, one or two interconnection trace can extend through slot 36 along a portion of edge surface 38 within an end of the slot, although the slot can have a width that allows more than two interconnection traces to fit along an end thereof.

In the embodiment shown in FIG. 1, edge surface 38 of slot 36 is angled such that the area of slot 36 on first surface 18 is greater than the area of slot 36 on second surface 20. Angle 80 between edge surface 38 and second surface 20 can be between 30° and 150°. In an embodiment, angle 80 can be between 50° and 130° or between 50° and 90°. Angle 80 can be about 54°, although other angles are possible. An angled edge surface 38 can facilitate formation of interconnection traces 40 therealong by methods discussed below. The angled configuration of edge surface 38 can result in slot 36 having different widths thereacross near first surface 18 and near second surface 20. For example the width near first surface 18 can be between about 50 microns to 250 microns, and the width near second surface 20 can be between about 10 microns and about 100 microns. In another embodiment, the width near first surface 18 can be between about 10 microns and about 100 microns, and the width near second surface 20 can be between about 50 microns and about 250 microns. Alternative configurations are possible, including ones in which the edge surface of the slot is inversely angled such that the area of slot on second surface is greater than on first surface. Additionally, the edge surface of the slot can have a different angle on opposing lateral sides thereof, or the edge surface can be substantially vertical. In other embodiments, the edge surface can be curved in either a concave or convex manner such that an angle is defined as an angle between end points of an arc formed by a cross-section of the edge surface or by an average slope of the edge surface along a height thereof.

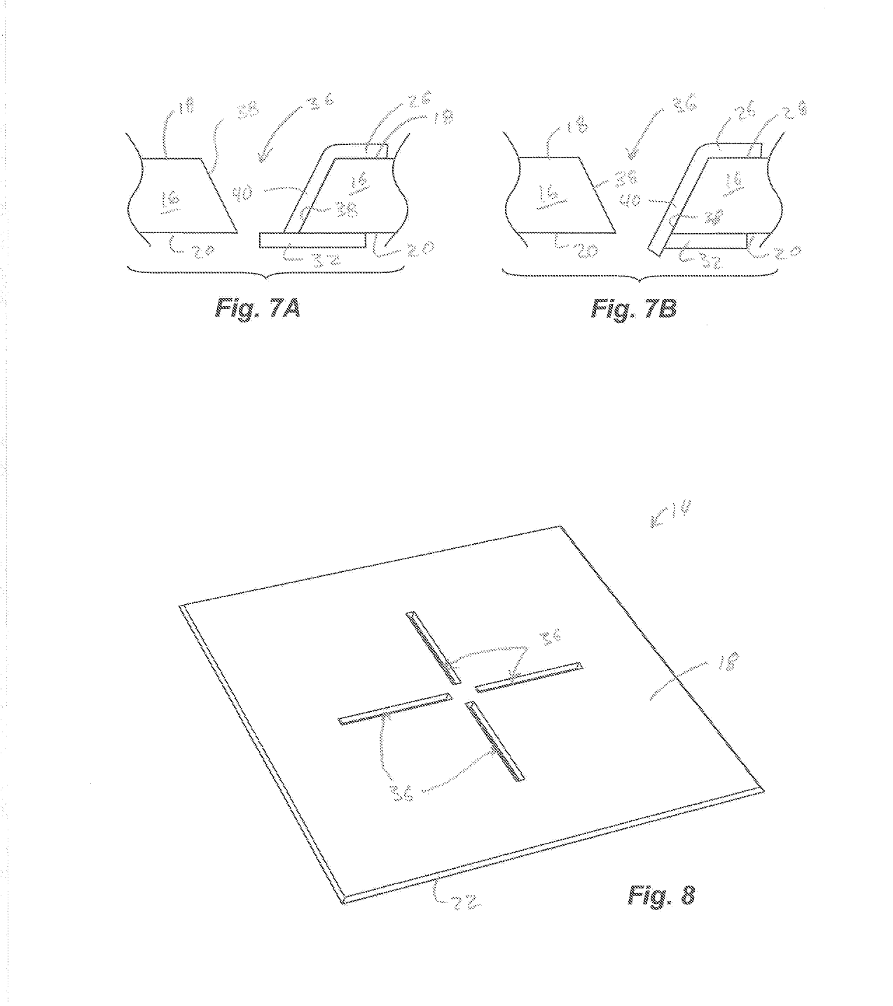

In an embodiment, interconnect traces 40 are integrally formed with either one or both of first traces 26 and second traces 32 such that they form a single trace having different segments thereof having the above-described characteristics of the first, second, and interconnection traces described above. In such an embodiment, interconnect traces 40 can be of the same material as first and second traces 26,32. Examples of connections between first, second, and interconnect traces are shown in FIGS. 7A and 7B. In FIG. 7A, second trace 32 extends along second surface 20 up to and past the intersection thereof with edge surface 38 such that a portion of second trace 32 is in registration with an open area within slot 36. Interconnect trace 40 is integrally formed with first trace 26 in a single element that extends along first surface and then along edge surface 38 toward second trace 32. Interconnect trace 38 contacts second trace 20 and has a portion extending therealong in a direction substantially parallel to second surface 20 in the area of second trace 20 that overlies the open area within slot 36. FIG. 7B shows an alternative arrangement in which interconnect trace 40 is integrally formed with first trace 26 and extends along edge surface 38 to and past the intersection thereof with second surface 20 such that interconnect trace 40 extends out of slot 36. Second trace 32 extends along second surface 20 to the intersection thereof with edge surface 38 such that it abuts the portion of interconnect trace 40 that extends out of slot 36. Other configurations are further possible, including one in which interconnect trace 38 extends out of slot 36 past both first and second surfaces 18,20, and in which first and second traces 26,32 abut the portions of interconnect trace that extend out of slot 36. In these and other embodiments, interconnect traces 40 can be of the same material as either or both of first and second traces 26,32. Further, interconnect traces 40 can be of a different material, including any of those discussed above with respect to first traces 26. Additionally, interconnect traces 40 can be of a conductive paste material or of a sintered matrix material that is deposited along edge surface 38. The configurations discussed above can be a product of various methods for forming the various traces and other features of interconnection component 14, including variations in sequences of similar methods.

By connecting a first trace 26 with a corresponding second trace 32 using an interconnect trace 40 that passes through slot 36, one or more first contact pad 28 can be electrically connected with one or more second contact pad 34. In an embodiment the arrangement described can electrically connect one first contact pad 28 with a corresponding second contact pad 34. Further, in an embodiment, multiple interconnect traces 40 can extend along edge surface 38 along the length thereof in a single slot 36 (which can be one of a plurality of slots with further interconnect traces 40 extending therethrough) to interconnect multiple pairs of corresponding first traces 26 and second traces 32. Thus, multiple corresponding pairs of first contact pads 28 can second contact pads 34 can be electrically connected through substrate 16. The corresponding first contact pads 28 and second contact pads 34 can be positioned in remote lateral locations along substrate 16 such as to be positioned in arrays of different pitches or to achieve different connection configurations with their associated components.

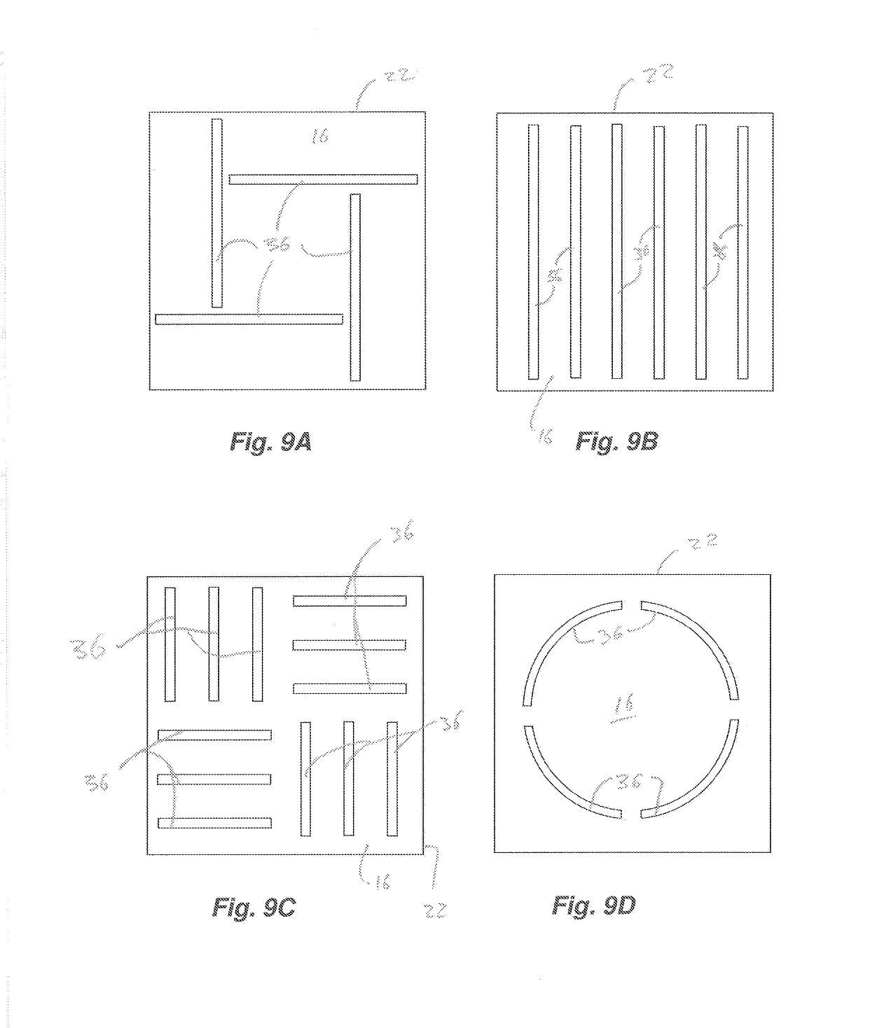

As mentioned previously, a plurality of slots can be formed in a single substrate, each including possibly multiple interconnect traces extending therethrough to connect multiple pairs of first and second traces. The plurality of slots can be arranged in endless configurations as dictated by the application and the design of the wiring connections therein. Examples of slot 36 configurations in a substrate 16 are shown in FIGS. 9A-9D. The slots 36 can be arranged to extend in different directions relative to each other and in different areas of substrate 16, as shown in FIGS. 9A and 9C. Slots 36 can extend substantially parallel to each other across substantially all of substrate 16, as shown in FIG. 9B. Further, slots 36 can be substantially arcuate and can align to form a circular arrangement, as shown in FIG. 9D. Multiple arcuate slots 36 can also be concentrically arranged over a greater area. Combinations of the exemplary arrangements are also possible, as are still further configurations. Additionally, there can be more or fewer slots in different regions of substrate 16 or there can be some regions with no slots at all. In an embodiment, slots 36 are configured to provide an adequate number of connections between wiring layers in locations that make such interconnections accessible for the wiring layers while providing adequate strength for substrate 16. In an embodiment, slots 36 can be filled with an underfill material 76 that surrounds and fills spaces between interconnect traces 38. Such an filling 76 can strengthen substrate 16 and can allow for some of either the first contacts 28 or second contacts 34 to be positioned so as to overlie slots 36.

The embodiment of interconnection component 14 described can, accordingly be used to achieve multiple electrical connections between elements connected with or bonded to opposing sides of interconnection component 14, such as microelectronic element 60 mounted over first surface 18 and circuit panel 70 to which package 12 is mounted with second surface 20 thereover. Accordingly interconnection component 14 can be used to facilitate electrical connection between components, such as microelectronic element 60 and circuit panel 70, which can include a printed circuit board or the like, having connections in arrays of different pitches or different connection configurations. Other multiple electric connections between other groups of components can be facilitated using appropriately configured interconnections made according to the principles described herein.

Another embodiment of an interconnection component 114 is shown in FIG. 2 as part of a microelectronic package 112 in an assembly 110 with a circuit panel 170. In this embodiment, interconnection component 114 is similar to interconnection component 14 discussed above with respect to FIG. 1, including the characteristics of substrate 116, which includes a slot 136 open to both first surface 118 and second surface 120, thereof. Interconnect traces 140 extend along edge surface 138 of slot 136 and connect first traces 126 with second traces 132 in corresponding pairs to achieve routing between components, such as microelectronic element 160 and circuit panel 170, connected with contact pads 128,134 on opposing sides of substrate 116.

Interconnection component 114 of the present embodiment can include one or more redistribution layers 148 over either or both of first and second surfaces 118,120 of substrate 116. Redistribution layers 148 can include additional wiring circuitry that overlies first or second wiring layers 124,130 and is connected therewith. In the embodiment shown redistribution layers 148 include a dielectric layer 56 with redistribution traces 150 embedded therein. Conductive vias 154 connect redistribution traces 150 with contact pads 128,134. Redistribution traces 150 are then connected with redistribution contacts 152 that are exposed at redistribution dielectric 156 for connection with external components, such as with contacts 166 of microelectronic element 160 or with contacts 172 of circuit panel 170. In this manner, redistribution layer 148 can provide additional routing of the circuitry within interconnection component beyond that included in first and second wiring layers 124,130 to provide contacts 152 in an array that can differ from those of first or second contacts 126,134 or to achieve different routing configurations for connections between external components.

Redistribution layer 148 can provide additional structural support for substrate 116. The additional structure of dielectric layer 148 overlying and bonded to first or second surface 118,120 of substrate 116 can give additional thickness for substrate 116. Such additional structure can also compensate for any strength in substrate 116 that is potentially lost due to the inclusion of slots 136 therethrough. This is in addition to any strength added by underfill 174 between microelectronic element 116 or underfill 176 within slot 136, as discussed above. In addition, redistribution layer 148 can substantially cover the openings formed by slot 136, allowing a redistribution contact 152A to be in a lateral position overlying slot 136. By this arrangement, the array configuration of redistribution contacts 152 can be made regardless of slot 136 location.

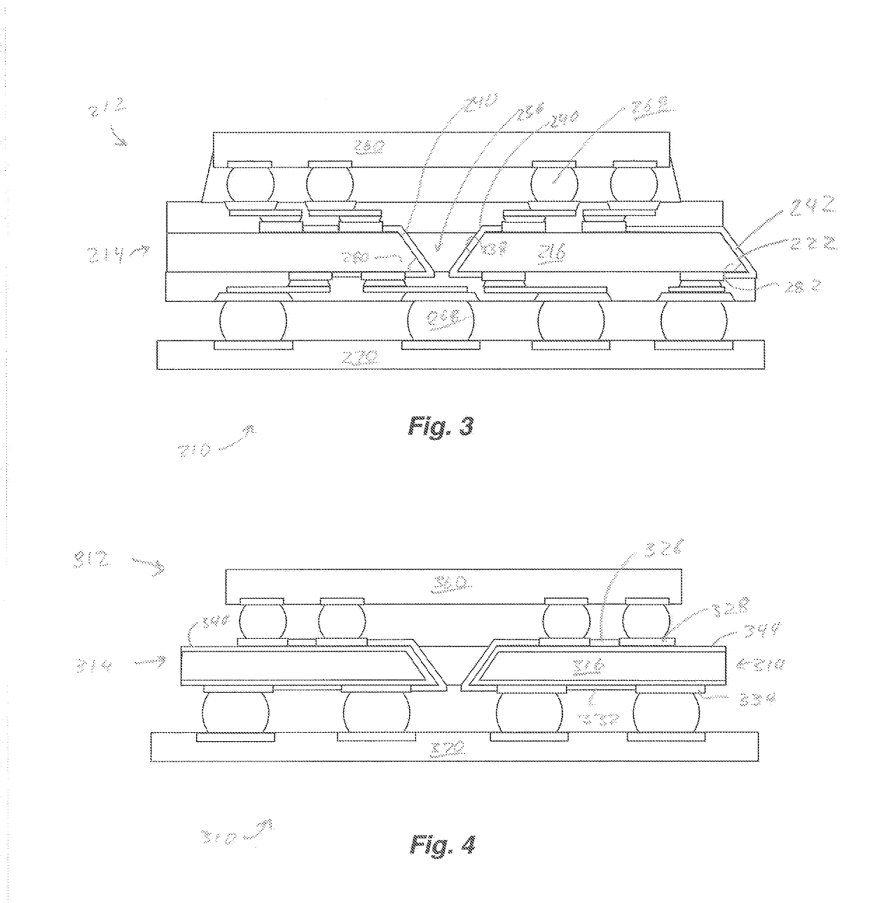

Another embodiment of an interconnection component 214 is shown in FIG. 3 as part of a microelectronic package 212 in an assembly 210 with a circuit panel 270. In this embodiment, interconnection component 214 is similar to interconnection component 14 discussed above with respect to FIG. 1, including the characteristics of substrate 216, which includes a slot 236 open to both first surface 218 and second surface 220, thereof. Interconnect traces 240 extend along edge surface 238 of slot 236 and connect first traces 226 with second traces 232 in corresponding pairs to achieve routing between components, such as microelectronic element 260 and circuit panel 270, connected with contact pads 228,234 on opposing sides of substrate 216. In the embodiment of FIG. 3, additional interconnect traces 242 extend along peripheral edge surface 222 of substrate 216 to form additional interconnects between first wiring layer 224 and second wiring layer 230. As shown in FIG. 3, peripheral edge 222 can be positioned at an angle 282 along one or more portions thereof with respect to second surface 220, which can facilitate interconnection trace 242 formation. Angle 282 can be substantially the same as angle 280 or can be different therefrom. Angle 282 can be within one of the ranges discussed above with respect to angle 280. In some embodiments, additional portions or sides of peripheral edge surface 222 can have interconnection traces 242 formed therealong to form additional connections between first and second wiring layers 224,230. Further, an embodiment of an interconnection component can include interconnection traces along the peripheral edge surface thereof an not include any slots formed through the substrate thereof.

FIG. 4 shows an embodiment of an interconnection component 314 included in a microelectronic assembly 310 that is similar to other embodiments discussed herein. In this embodiment, substrate 316 can be made of a semi-conductive or conductive material. In an example substrate 316 is made from a semiconductor such as ceramic or silicon. A dielectric coating 344 overlies substrate 316, including over first and second surfaces 318,320 thereof and over edge surface 338 of slot 336. First and second wiring layers 324,330 and interconnect traces 340 are exposed on coating 344 and are spaced apart from substrate 316 thereby to prevent shorting between these conductive elements through substrate 316. Additionally, coating 344 can further cover peripheral edge surface 322 of substrate 316 in an embodiment where interconnect traces 342 extend therealong, such as shown in FIG. 3.

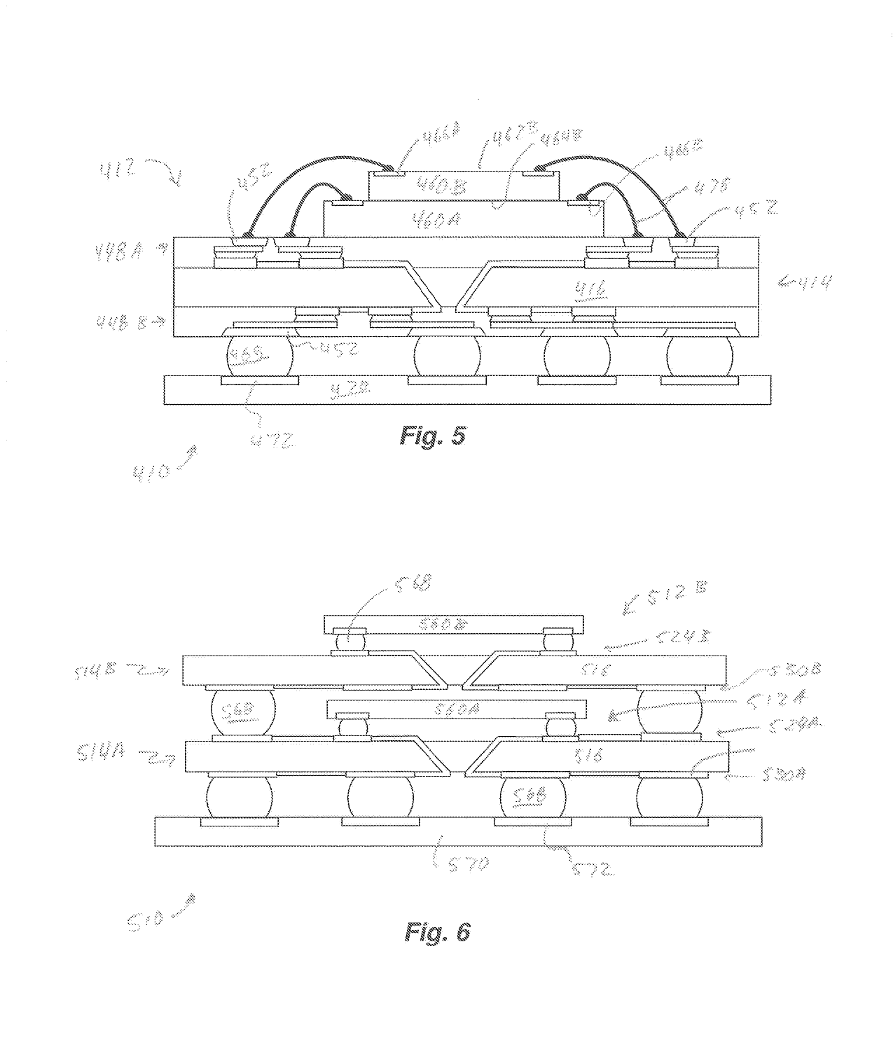

A microelectronic package 412 such as that shown in FIG. 5 in an assembly 410 with circuit panel 470 can include multiple microelectronic elements 460A and 460B on a single interconnection component 414. In the embodiment shown microelectronic elements 460A and 460B are shown bonded face-up in a stack over redistribution dielectric 456, although other arrangements are possible, including combinations of face-up or flip-chip bonding or multiple flip-chips. Further, microelectronic elements 460A and 460B can be mounted next to each other along redistribution dielectric 456. Such multi-element arrangements can be made on other embodiments of interconnection components described herein. In the embodiment shown redistribution contacts 452 are configured to be positioned in a region surrounding microelectronic element 460A to facilitate connection therewith using wire bonds 478 although other configurations are possible.

FIG. 6 shows a further multi-element arrangement wherein each microelectronic element 560A and 560B are included in separate packages 512A and 512B including interconnection components 514A and 514B that are configured to facilitate such a stacked arrangement. In the embodiment shown, interconnection components 514 are similar to interconnection components 14 described above with respect to FIG. 1, although other embodiments of interconnection components discussed herein can be similarly adapted to be used in a stacked arrangement similar to the one shown in FIG. 6. As shown, interconnection component 514A includes first contact pads 528, some of which are configured for connection with microelectronic contacts 562, and others of which are laterally outside the area beneath microelectronic element 560 so as to be accessible for connection with second contact pads 534 of interconnection component 514B. In the embodiment shown solder balls 568 are shown bonding first contact pads 528 of interconnection component 514A with second contact pads 534 of interconnection component 514B, but other structures such as pins or posts, alone or in combination with solder or other conductive bonding materials are possible.

A method for making an interconnection component such as interconnection component 14 shown in FIG. 1 can include the step of making a substrate 16 as shown in FIG. 8. Substrate 16 is made by processing a sheet of material to make the desired form as described above with reference to FIGS. 1-5. As previously discussed, substrate can be made from a sheet of a dielectric material such as polyimide that is of the desired thickness. The sheet can be cut to the desired length and width from the sheet in a chip-scale type method. Alternatively, the sheet can be left in a wafer and processed before cutting into individual units in a wafer-level method. In the embodiment shown, substrate 16 has been cut to the desired size and trenches 36 have been formed therein through substrate 16 and open to both the first surface 18 and the second surface 20. Substrate 16 can be cut and slots 36 can be formed by varying means including sawing, etching, such as laser etching or the like, milling, etc. The methods used for cutting and slot formation can be the same or can be different. The angle 80 of edge surfaces 38 of slots 36 as well as the angle 82 of peripheral edge surfaces 22 can be formed by the cutting or slot formation process or can be formed after cutting or slot formation by a different process such as grinding or chemical etching, for example. In an embodiment substrate 16 can be of a semiconductor material with a dielectric coating applied thereto after slot formation and also, if desired, after cutting.

Slots 36 are shown in FIG. 8 in a “t” or “x” shape extending generally outward from the center of the substrate 16. Other configurations for slots 36 are possible and can be made to match the desired routing circuitry for interconnection component 14. Such possible arrangements include the examples shown in FIGS. 9A-9D, which are discussed further above.

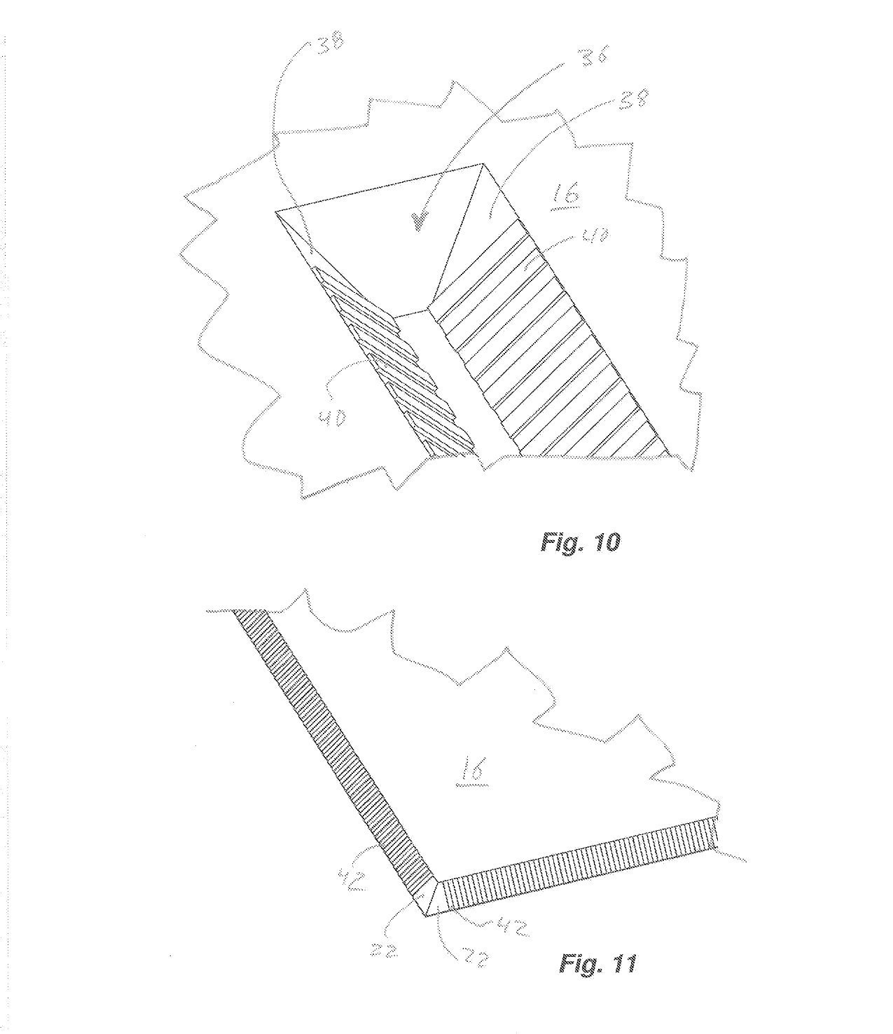

FIGS. 10 and 11 show the substrate 16 from FIG. 8 having interconnect traces 40 and 42 formed respectively along edge surface 38 of slot 36 and along peripheral edge surface 22. These interconnect traces 40 and 42 can be in either of the configurations shown in FIGS. 7A and 7B and discussed above or in other configurations as needed for the desired structure and formation process. In an embodiment, second traces 32 and second contact pads 34 (not shown in FIG. 10) can be formed first using a process such as plating a solid metal layer on second surface and then etching that pattern to form the desired wiring pattern therein. This can be done before or after forming slot 36 or applying a dielectric coating (such as coating 344 in FIG. 4) over edge surface 38 or 22. After formation of second traces 32, a separate solid metal layer can be formed over first surface 18 and edge surface 38 (the solid metal layer can also be formed over peripheral edge surface 22 if traces are desired thereover as well). That metal layer can then be etched to form interconnect traces 38, as shown in FIG. 10, and interconnect traces 40, as shown in FIG. 11, along with first traces 26 and first contract pads 28 (not shown in FIGS. 10 and 11) along first surface 18 in a desired pattern for first wiring layer 24.

In other embodiments of the method, the first and second wiring layers 24 and 30 can be formed by electroless plating on a seed layer formed for example using lithography or other methods. In such an embodiment, interconnect traces 40 or can be formed integrally with either the first or second wiring layers 24 or 30 by patterning the seed layer along edge surface 38 or peripheral edge surface 22. Alternatively, in this embodiment or the embodiment discussed above, interconnect traces 40 or 42 can be formed by depositing a conductive paste material or a sintered conductive matrix material in the desired locations for interconnect traces 40 or 42 and allowing the material to cure. In an embodiment, at least portions of the first or second wiring layers 24 or 30 can also be formed by depositing such materials in the same or additional steps as the deposition of the material for interconnect traces 40 or 42.

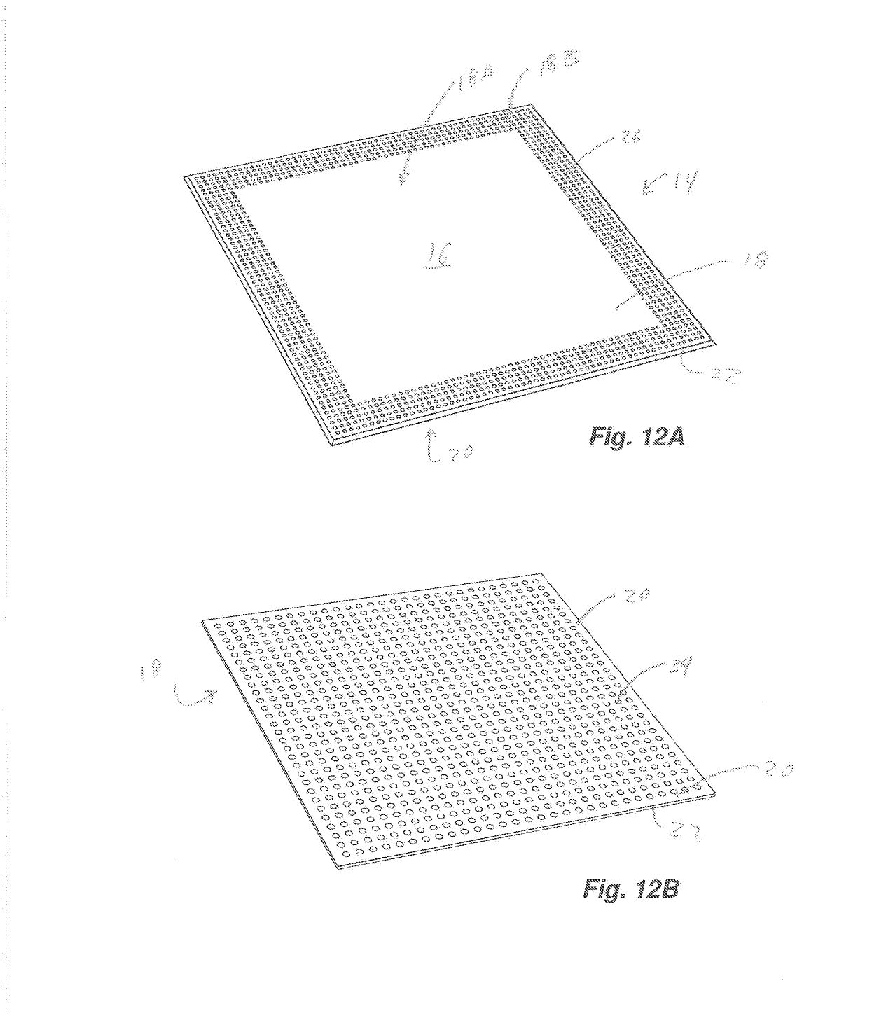

FIGS. 12A and 12B show, respectively, top and bottom perspective views of interconnection component 14 after formation of redistribution layers 48A and 48B, respectively over first 18 and second 20 surfaces of substrate 16. Redistribution layers 48A,48B can be formed by depositing a first portion of redistribution dielectric over, for example, first surface 18 and then forming vias to expose first contact pads 28 that can then be filled with conductive material to make conductive vias 54. Redistribution traces 50 can then be formed over the dielectric layer portion connected with the conductive vias 54. The remaining portion of redistribution dielectric 56 can then be formed to embed traces 50 therein. Additional openings can then be formed in redistribution dielectric 56 to expose portions of traces and redistribution contacts 52 can be formed therein exposed on redistribution dielectric 56, as shown in FIGS. 12A and 12B. Redistribution layers 48A,48B can cover slots 36, as shown, and can include contacts such as redistribution contacts 52 that overlie slots 36.

As shown in FIG. 12A redistribution contacts 52 (or other contacts in other embodiments) can be located within a single region of interconnection component 14 or can be differently configured between separate regions. Such regions can be configured to connect to a microelectronic element such as by flip-chip bonding or can be configured to connect to another package in a stacked assembly. FIG. 12A shows contacts having been formed in second region 18B for connection to another package in a stacked arrangement. Additional contacts 52 can also be formed in first region 18A for connection to a microelectronic element.

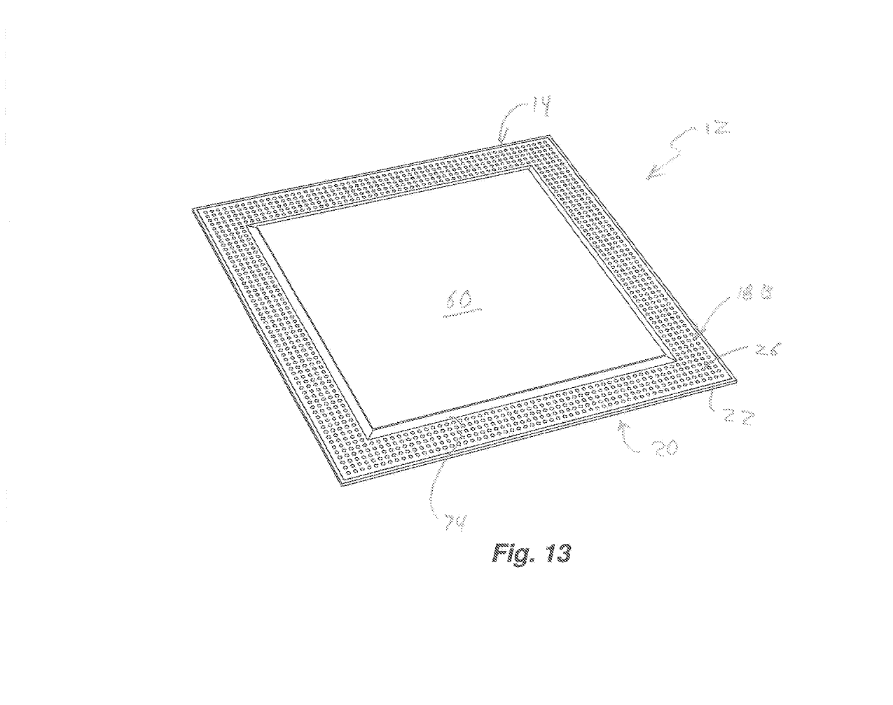

FIG. 13 shows a package 12 in which a microelectronic element 60 has been mounted over first surface 18 of interconnection component 14, contacts 52 for connection with element contacts 66 having been formed in first region 18A in a subsequent step. The package 12 can be assembled with a circuit panel, such as circuit panel 70 shown in FIG. 1 or over another package 12 in a stacked arrangement. Additionally, package 12 can be assembled with one or more other packages in a stacked arrangement as shown in FIG. 6.

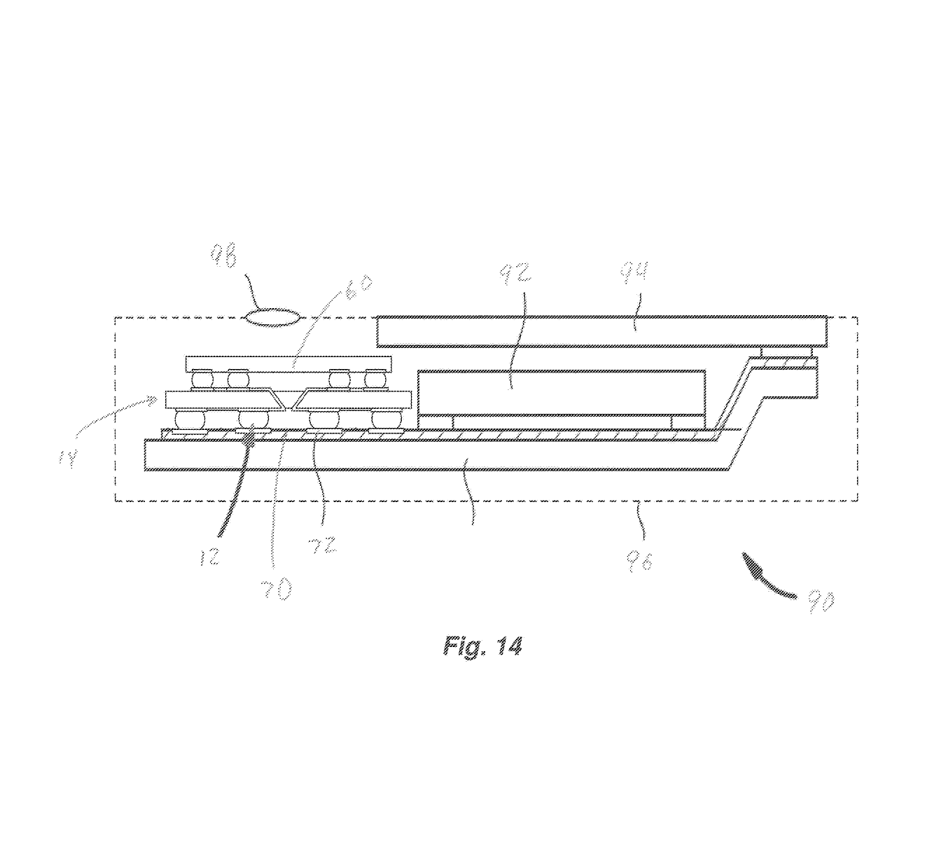

Various embodiments of the interconnection components described herein can be used in connection with various diverse electronic systems. The interconnection components described above can be utilized in construction of diverse electronic systems, as shown in FIG. 14. For example, a system 90 in accordance with a further embodiment of the invention can include a microelectronic package 12, being a unit formed by assembly of a microelectronic element 60 with an interconnection component 14, similar to the microelectronic assembly of a microelectronic element 60 and interconnection component 14 as shown in FIG. 1. The embodiment shown, as well as other variations of the interconnection component or assemblies thereof, as described above can be used in conjunction with other electronic components 92 and 94. In the example depicted, component 92 can be a semiconductor chip or package or other assembly including a semiconductor chip, whereas component 94 is a display screen, but any other components can be used. Of course, although only two additional components are depicted in FIG. 14 for clarity of illustration, the system may include any number of such components. In a further variant, any number of microelectronic packages or assemblies including a microelectronic element and an interconnection component can be used. The microelectronic package and components 92 and 94 are mounted in a common housing 96, schematically depicted in broken lines, and are electrically interconnected with one another as necessary to form the desired circuit. In the exemplary system shown, the system includes a circuit panel 70 such as a flexible printed circuit board, and the circuit panel includes numerous conductors 72 interconnecting the components with one another. However, this is merely exemplary; any suitable structure for making electrical connections can be used, including a number of traces that can be connected to or integral with contact pads or the like. Further, circuit panel 70 can connect to interconnection component 14 using solder balls 68 or the like. The housing 96 is depicted as a portable housing of the type usable, for example, in a cellular telephone or personal digital assistant, and screen 94 is exposed at the surface of the housing. Where system 90 includes a light-sensitive element such as an imaging chip, a lens 98 or other optical device also may be provided for routing light to the structure. Again, the simplified system 90 shown in FIG. 14 is merely exemplary; other systems, including systems commonly regarded as fixed structures, such as desktop computers, routers and the like can be made using the structures discussed above.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An interconnection component, comprising:
a substrate having first and second opposed major surfaces defining a thickness of less than 1000 microns and a first slot extending between the first and second surfaces, the first slot being enclosed by the substrate at the first and second surfaces and defining an edge surface between the first surface and the second surface;
first conductive traces extending along the first surface and electrically connected with first contact pads that overlie the first surface;
second conductive traces extending along the second surface and electrically connected with second contact pads that overlie the second surface; and
interconnect traces extending along the edge surface of the first slot, each interconnect trace directly connecting at least one first trace with at least one second trace.

2. The interconnection component of claim 1, wherein the first slot has a length in the first lateral direction and a width in a second lateral direction perpendicular to the first lateral direction, and wherein the length and width define a ratio of at least 10 to 1.

3. The interconnection component of claim 1, wherein at least ten interconnect traces along the edge surface of the first slot.

4. The interconnection component of claim 1, wherein the first and second contact pads are usable to bond the interconnection component to at least one of a microelectronic element or a circuit panel, at least one of the first contact pads or the second contact pads configured for bonding to element contacts on a face of a microelectronic element and at least one of the first contact pads or the second contact pads configured for bonding to circuit contacts on a face of a circuit panel.

5. The interconnection component of claim 1, wherein the first traces are included in a first redistribution layer that overlies the first surface of the substrate, wherein the interconnection component further includes a second redistribution layer overlying the first redistribution layer, and wherein the first contact pads are included in the second redistribution layer.

6. The interconnection component of claim 5, wherein the second redistribution layer has third traces formed therein that are electrically connected to the first traces, and wherein the first contact pads are joined to the third traces.

7. The interconnection component of claim 6, wherein at least one of the third traces has at least a portion in registration with an open area within the first slot.

8. The interconnection component of claim 6, wherein a first dielectric layer overlies at least portions the first surface of the substrate and fills spaces between the first and third traces.

9. The interconnection component of claim 8, wherein the first dielectric further layer fills at least some of the first slot.

10. The interconnection component of claim 5, wherein the second traces are included in a third redistribution layer that overlies the second surface of the substrate, wherein the interconnection component further includes a fourth redistribution layer overlying the third redistribution layer, and wherein the second contact pads are included in the fourth redistribution layer.

11. The interconnection component of claim 10, wherein the fourth redistribution layer has fourth traces formed therein that are electrically connected to the second traces, and wherein the second contact pads are joined to the fourth traces.

12. The interconnection component of claim 1, wherein the first traces are in a first redistribution layer, wherein the interconnection component further includes a plurality of additional redistribution layers overlying the first redistribution layer, one of the additional redistribution layer being an outermost redistribution layer, and wherein the first contact pads are in the outermost redistribution layer.

13. The interconnection component of claim 1, wherein at least one of the first or second contact pads are displaced in one or more lateral directions from a boundary of the first slot.

14. The interconnection component of claim 1, wherein at least one of the first or second contact pads overlies at least a portion of the first slot.

15. The interconnection component of claim 1, wherein the substrate further includes a second slot formed therethrough that is open to the first surface and the second surface, and wherein the interconnection component further includes interconnect traces extending along the edge surface of the second slot, each interconnect trace directly connecting at least one first trace with at least one second trace.

16. The interconnection component of claim 1, wherein the first slot is one of a plurality of slots included in the substrate, each slot being open to the first surface and the second surface, the interconnection component including interconnect traces extending along the edge surface of each of the plurality of slots, each interconnect trace directly connecting at least one first trace with at least one second trace.

17. The interconnection component of claim 1, wherein the first slot is non-linear.

18. The interconnection component of claim 1, wherein the first slot is filled with a dielectric material that extends along portions of the edge surface uncovered by the interconnect traces and fills spaces between the interconnect traces.

19. The interconnection component of claim 1, wherein the substrate is of a material having a coefficient of thermal expansion (“CTE”) of less than about 10 parts per million per degree, Celsius (PPM/° C.).

20. The interconnection component of claim 19, wherein the material is selected from the group consisting of: silicon, glass, ceramic, liquid crystal polymer, or combinations thereof.

21. The interconnection component of claim 1, wherein the substrate includes an inner layer of a semiconductor material and an outer layer overlying the inner layer and of a dielectric material, and wherein the outer layer defines the first surface, the second surface and the edge surface of the first slot.

22. The interconnection component of claim 21, wherein the outer layer further defines a peripheral edge.

23. The interconnection component of claim 1, wherein the substrate defines a peripheral edge extending between the first and second surfaces, and wherein at least some interconnect traces further extend along the peripheral edge and directly connect at least one first trace with at least one second trace.

24. The interconnection component of claim 1, wherein the first slot has a first width adjacent the first surface and a second width adjacent the second surface, the first width being between about 50 and 250 microns and the second width being between about 10 and 100 microns.

25. The interconnection component of claim 1, wherein the edge surface of the first slot defines a first angle with the second surface of between about 30 degrees and 150 degrees.

26. The interconnection component of claim 25, wherein the edge surface of the first slot defines a first angle with the second surface of between about 50 degrees and 130 degrees.

27. The interconnection component of claim 25, wherein the first angle is about 54 degrees.

28. A microelectronic assembly, including:
a microelectronic element having a first surface, a second surface spaced apart from the first surface, and conductive contacts exposed at the first surface; and
an interconnection component according to claim 1;
wherein the microelectronic element is mounted on the interconnection component over the first side of the substrate, and wherein the conductive contacts are electrically connected to at least some of the first contact pads.

29. The microelectronic assembly of claim 28, wherein the microelectronic element is a first microelectronic element, the assembly further including a second microelectronic element having a first surface, a second surface spaced apart from the first surface, and conductive contacts exposed at the first surface, wherein the second microelectronic element is mounted on the interconnection component such that at least some of the contacts thereof are electrically interconnected to at least some of the first contact pads.

30. The microelectronic assembly of claim 29, wherein the first and second microelectronic elements are electrically interconnected with one another through the interconnection component.

31. The microelectronic assembly of claim 28, wherein the contacts face the first contact pads and are joined thereto.

32. The microelectronic assembly of claim 28, further including solder balls joined to at least some of the second contact pads.

33. A microelectronic system, including:
a microelectronic assembly according to claim 28 and one or more other electronic components electrically connected to the microelectronic assembly.

34. The microelectronic system of claim 33, wherein the interconnection component wherein at least one of the other electronic components is one of an active or passive device.

35. An interconnection component, comprising:
a substrate having first and second opposed major surfaces defining a thickness of less than 1000 microns and a first slot extending between the first and second surfaces, the first slot being enclosed by the substrate at the first and second surfaces and defining a first edge surface between the first surface and the second surface, and a second edge surface extending between outer peripheries of the first surface and the second surface;
first conductive traces extending along the first surface and electrically connected with first contact pads that overlie the first surface;
second conductive traces extending along the second surface and electrically connected with second contact pads that overlie the second surface;
first interconnect traces extending along the first edge surface of the first slot; and
second interconnect traces extending along the second edge surface of substrate;
wherein each of the first and second interconnect traces directly connect at least one first trace with at least one second trace.

36. A method for making an interconnection component, comprising:
forming a first slot in a substrate having first and second opposed major surfaces defining a thickness of less than 1000 microns, the first slot being enclosed by the substrate at the first and second surfaces and defining an edge surface between the first surface and the second surface;
forming first conductive traces extending along the first surface, second conductive traces extending along the second surface, and interconnect traces extending along portions of the edge surface of the first slot such that each interconnect trace directly connects at least one first trace with at least one second trace; and
forming first contact pads overlying portions of the first surface and electrically connected with at least some of the first traces and second contact pads overlying portions of the second surface and electrically connected with at least some of the second traces.

37. The method of claim 36, wherein the interconnect traces are formed simultaneously with and by the same process as one of the first traces and the second traces.

38. The method of claim 36, wherein at least one of the first or second traces is formed from a single metal layer from which the first or second contact pads are respectively formed.

39. The method of claim 36, wherein a first metal layer is used to form the first traces, and wherein a second metal layer overlying the first traces is used to form the first contact pads.

40. The method of claim 36, wherein the substrate is of a semiconductor material, the method further including the step of forming a dielectric coating over the substrate prior to the steps of forming traces and forming contact pads.

41. The method of claim 40, wherein the dielectric coating substantially covers the first and second opposed surfaces and the edge surface of the slot.

42. The method of claim 36, wherein the first slot is formed such that the edge surface forms an angle with the second surface that is between about 30 degrees and 150 degrees.

43. The method of claim 42, wherein the first slot is formed by a first step including removing material from the substrate to give the first slot a desired length and width and a second step including forming the angle of the edge surface.

44. The method of claim 36, wherein the first slot is one of a plurality of slots, each slot having some of the interconnect traces formed along respective edge surfaces thereof.

45. The method of claim 36, wherein some of the interconnect traces are further formed extending along portions of the peripheral edge of the substrate, wherein corresponding pairs of at least some of the first and second traces extend to a boundary of the peripheral edge, and wherein corresponding interconnect traces are bonded between and connect the corresponding pair of a first trace and a second trace.

46. The method of claim 36, wherein the first traces are formed in a first redistribution layer, wherein the method further includes forming at least one additional redistribution layer overlying the first redistribution layer, one of the additional redistribution layer being an outer redistribution layer, and wherein the first contact pads are formed in the outermost redistribution layer.

47. The method of claim 46, further including forming a first dielectric layer overlying at least portions the first surface of the substrate and filling spaces between the traces, wherein the first contact pads are exposed at a surface of the first dielectric layer.

48. The method of claim 36, wherein at least one of the first or second contact pads is formed in a location such that it is displaced in one or more lateral directions from a boundary of the first slot.

49. The method of claim 36, wherein at least one of the first or second contact pads are formed overlying at least a portion of the first slot.

50. The method of claim 36, further including the step of filling the first slot with a dielectric material that extends along portions of the edge surface uncovered by the interconnect traces and fills spaces between the interconnect traces.

51. The method of claim 36, wherein the first traces and the interconnect traces are formed by plating a first conductive layer over the first surface of the substrate and the edge surface of the first slot and removing portions of the first conductive layer.

52. The method of claim 51, wherein the second traces are formed by plating a second conductive layer on the second surface of the substrate and removing portions of the second conductive layer.

53. The method of claim 36, wherein the first and second traces and the interconnect traces are formed by depositing conductive metal using one of laser writing or printing.

54. A method for making a microelectronic package, including the steps of:
assembling a microelectronic element having a front face, a back face remote from the front face, and contacts exposed at the front face with a substrate having:
first and second opposed major surfaces defining a thickness of less than 1000 microns and a first slot formed therethrough extending between the first and second surfaces, the first slot being enclosed by the substrate at the first and second surfaces and defining an edge surface between the first surface and the second surface;
first conductive traces extending along the first surface and electrically connected with first contact pads that overlie the first surface;
second conductive traces extending along the second surface and electrically connected with second contact pads that overlie the second surface; and
interconnect traces extending along the edge surface of the first slot, each interconnect trace directly connecting at least one first trace with at least one second trace, wherein corresponding pairs of at least some of the first and second traces extend to directly contact respective ones of the interconnect traces, and wherein the respective interconnect traces are bonded between and connect the corresponding pair of a first trace and a second trace;
wherein the microelectronic element is assembled with the substrate such that the microelectronic element is bonded to the interconnection component over the first surface of the substrate and the contacts are electrically connected to at least some of the first contact pads.

55. The method of claim 54, wherein the contacts face the first contact pads and are joined thereto.

56. The method of claim 54, further including forming solder balls on at least some of the second contact pads.

57. The method of claim 54, wherein the contacts face away from the first contacts pads and are electrically connected therewith using wire bonds.
